(19) United States
(12) Patent Application Publication
(10) Pub. No.: US 2024/0332110 A1
(43) Pub. Date: Oct. 3, 2024

(54) Multi-Chip Package with Detachable Chips

(71) Applicant: Western Digital Technologies, Inc., San Jose, CA (US)

(72) Inventors: Rotem Sela, Sunnyvale, CA (US); Mahmud Asfur, Bat Yam (IL); Boaz Greenberg, Bat Yam (IL)

(73) Assignee: Western Digital Technologies, Inc., San Jose, CA (US)

(21) Appl. No.: 18/361,147

(22) Filed: Jul. 28, 2023

Related U.S. Application Data
(60) Provisional application No. 63/492,836, filed on Mar. 29, 2023.

(51) Int. Cl. H01L 23/32; H01L 23/00; H01L 23/40; H01L 23/498; H01L 25/18; H01R 13/502; H01R 33/88; H10B 80/00

(52) U.S. Cl. CPC H01L 23/32; H01L 23/40; H01L 23/49833; H01L 24/72; H01L 25/18; H01R 13/502; H01R 33/88; H10B 80/00; H01L 23/49811; H01L 24/32; H01L 2224/32225; H01L 2224/72

(57) ABSTRACT

A multi-chip package includes a substrate, a first semiconductor module mounted on the substrate, an interposer mounted on the first semiconductor module and a second semiconductor module detachably coupled to the interposer. A housing at least partially encloses the first and second semiconductor modules and the interposer. The housing is configured to transition between a closed configuration and an open configuration. In the closed configuration, the second semiconductor module is fixed in position relative to the interposer and electrically connected to the substrate via the interposer, and in the open configuration the second semiconductor module is detachable from the interposer. The second semiconductor module being detachable from the interposer allows for the second semiconductor module to be selectively replaced to improve the longevity of the multi-chip package.

### CROSS-REFERENCE TO RELATED APPLICATIONS

This application claims the benefit of U.S. Provisional Patent Application No. 63/492,836 filed Mar. 29, 2023 entitled “Multi-Chip Package with Detachable Chips”, which is incorporated by reference herein in its entirety.

### BACKGROUND

The present disclosure generally relates to multi-chip packages, more particularly, to a multi-chip package having one or more detachable semiconductor modules or chips.

Multi-chip packages (MCP) commonly include a plurality of chips fixedly connected to a multilayer circuit board via bond wires and encased within an encapsulant. The chips included in the MCP may be, for instance, a combination of dynamic random access memory (DRAM) modules and NAND modules. For example, in recent years MCPs designed for use in mobile devices such as smartphones and tablets typically include a DRAM module and a NAND module fixedly coupled to a printed circuit board (PCB) and encased within an encapsulant. The individual DRAM and NAND modules (or chips) of conventional MCPs are permanently attached to the PCB (e.g., via wire bonds or solder bonds) and as such, in instances where one of the NAND or DRAM modules is broken or defective, the entire MCP becomes unusable. Additionally, the NAND module of conventional MCPs is not replaceable with another NAND module having a higher storage capacity. Therefore, there is a need to provide an MCP with chips, modules and/or modules configured to be detachably coupled thereto such that broken or failed modules may be replaced and/or to allow for the storage capacity of the MCP to be increased.

### SUMMARY

In one embodiment there is a multi-chip package including a substrate, a first semiconductor module mounted directly on a top planar surface of the substrate and electrically connected thereto, an interposer mounted on the first semiconductor module and electrically connected to the substrate, a second semiconductor module detachably coupled to the interposer, and a housing at least partially enclosing the first and second semiconductor modules and interposer, the housing configured to transition between a closed configuration and an open configuration. In the closed configuration, the second semiconductor module may be fixed in position relative to the interposer and electrically connected to the substrate via the interposer, and in the open configuration the second semiconductor module may be detachable from the interposer.

In some embodiments, the first semiconductor module is a NAND module and the second semiconductor module is a dynamic random access memory (DRAM) module. In some embodiments, the first semiconductor module is a DRAM module and the second semiconductor module is a NAND module. In some embodiments, the housing includes a base plate coupled to the substrate and a cover movably coupled to the base plate, the cover being movable from a first position in the closed configuration to a second position in the open configuration. In some embodiments, in the first position the cover abuts against the second semiconductor module and biases the second semiconductor module towards the interposer, and in the second position the cover is configured to permit detachment of the second semiconductor module from the interposer. In some embodiments, the second semiconductor module is coupled to the cover such that the second semiconductor module is movable relative to the base plate with the cover.

In some embodiments, the cover comprises a heat sink composed of a material having a thermal conductivity of at least about 150 W/m*K. In some embodiments, in the closed configuration the second semiconductor module is stacked on the first semiconductor module, and the interposer is disposed between the first semiconductor module and the second semiconductor module. In some embodiments, the interposer includes a first plurality of conductive pads, and the second semiconductor module includes a second plurality of conductive pads configured to directly contact the first plurality of conductive pads when the housing is in the closed configuration. In some embodiments, in the closed configuration the cover is configured to apply an amount of pressure on the second semiconductor module and first semiconductor module sufficient to prevent the first and second plurality of conductive pads from moving out of direct contact with one another. In some embodiments, there are a plurality of bond wires electrically connecting the interposer to the substrate.

In another embodiment, there is a multi-chip package including a substrate, a first semiconductor module detachably coupled to the substrate, a second semiconductor module detachably coupled to the substrate and spaced from the first semiconductor module, and a housing at least partially enclosing the first and second semiconductor modules, the housing configured to transition between a closed configuration and an open configuration, the housing including a base plate and a cover movably coupled to the base plate, the cover being movable from a first position in the closed configuration to a second position in the open configuration. In the closed configuration, the first and second semiconductor modules are fixed in position relative to the substrate and electrically connected to the substrate, and in the open configuration the first and second semiconductor modules are detachable from the substrate. In the first position the cover abuts against the first and second semiconductor modules and biases each towards the substrate, and in the second position the cover is configured to permit detachment of the first and second semiconductor modules from the substrate.

In some embodiments, the first semiconductor module is a NAND module and the second semiconductor module is a dynamic random access memory (DRAM) module. In some embodiments, the cover comprises a heat sink composed of a material having a thermal conductivity of at least about 150 W/m*K. In some embodiments, the substrate includes a first and second set of conductive pads, the first semiconductor module includes a third set of conductive pads, and the second semiconductor module includes a fourth set of conductive pads, the third and fourth sets of conductive pads configured to directly contact the corresponding first and second set of conductive pads when the housing is in the closed configuration. In some embodiments, in the closed configuration the cover is configured to apply an amount of pressure on the second semiconductor module and first semiconductor module sufficient to prevent the first, second, third and fourth sets of conductive pads from moving out of direct contact with one another. In some embodiments, the first and second semiconductor modules are coupled to the cover such that the first and second semiconductor modules are moveable relative to the base plate with the cover, and wherein the substrate is coupled to the base plate.

In another embodiment there is a multi-chip package including a substrate, a first semiconductor module mounted directly on a top planar surface of the substrate and electrically connected thereto, the first semiconductor module including a first plurality of magnets, a second semiconductor module mounted to the first semiconductor module and including a second plurality of magnets detachably coupling the second semiconductor module to the first semiconductor module, and a housing at least partially enclosing the first and second semiconductor modules, the housing configured to transition between a closed configuration and an open configuration. In the closed configuration, the second semiconductor module is fixed in position relative to the first semiconductor module and electrically connected to the substrate, and in the open configuration the second semiconductor module is detachable from the first semiconductor module.

In some embodiments, the first semiconductor module is a NAND module and the second semiconductor module is a dynamic random access memory (DRAM) module. In some embodiments, the first semiconductor module is a DRAM module and the second semiconductor module is a NAND module.

### BRIEF DESCRIPTION OF THE DRAWINGS

The foregoing summary, as well as the following detailed description, will be better understood when read in conjunction with the appended drawings. For the purpose of illustrating the present disclosure, there are shown in the drawings embodiments, which are presently preferred, wherein like reference numerals indicate like elements throughout. It should be noted, however, that aspects of the present disclosure can be embodied in different forms and thus should not be construed as being limited to the illustrated embodiments set forth herein. The elements illustrated in the accompanying drawings are not necessarily drawn to scale, but rather, may have been exaggerated to highlight the important features of the subject matter therein. Furthermore, the drawings may have been simplified by omitting elements that are not necessarily needed for the understanding of the disclosed embodiments.

In the drawings:

FIG. 1 is side cross-sectional view of a multi-chip package (MCP) including first and second semiconductor modules in a closed configuration in accordance with an exemplary embodiment of the present disclosure;

FIG. 2 is a side cross-sectional view of the MCP of FIG. 1 in an open configuration and showing decoupling of the second semiconductor module from the first semiconductor module according to an exemplary embodiment;

FIG. 3 is a bottom elevational view of the second semiconductor module of the MCP of FIG. 1;

FIG. 4 is a side cross-sectional view of the MCP of FIG. 1 in the open configuration showing the second semiconductor module being detached;

FIG. 5 is a side cross-sectional view of an MCP in a closed configuration and in accordance with another exemplary embodiment of the present disclosure;

FIG. 6 is a side cross-sectional view of the MCP of FIG. 5 in an open configuration;

FIG. 7 is a side cross-sectional view of an MCP in a closed configuration and in accordance with another exemplary embodiment of the present disclosure;

FIG. 8 is a side cross-sectional view of the MCP of FIG. 7 in an open configuration and showing decoupling of the semiconductor modules according to an exemplary embodiment of the present disclosure;

FIG. 9 is a side cross-sectional view of an MCP in a closed configuration and in accordance with another exemplary embodiment of the present disclosure; and

FIG. 10 is a side cross-sectional view of the MCP of FIG. 9 in an open configuration and showing decoupling of the second semiconductor module from the first semiconductor module according to an exemplary embodiment of the present disclosure.

### DETAILED DESCRIPTION

The present subject matter will now be described more fully hereinafter with reference to the accompanying Figures, in which representative embodiments are shown. The present subject matter can, however, be embodied in different forms and should not be construed as limited to the embodiments set forth herein. Rather, these embodiments are provided to describe and enable one of skill in the art.

Numerous details are described herein in order to provide a thorough understanding of the example embodiments illustrated in the accompanying drawings. However, some embodiments may be practiced without any of the specific details, and the scope of the claims is only limited by those features and aspects specifically recited in the claims. Furthermore, well-known methods, components, and circuits have not be described in exhaustive detail so as not to unnecessarily obscure pertinent aspects of the embodiments described herein.

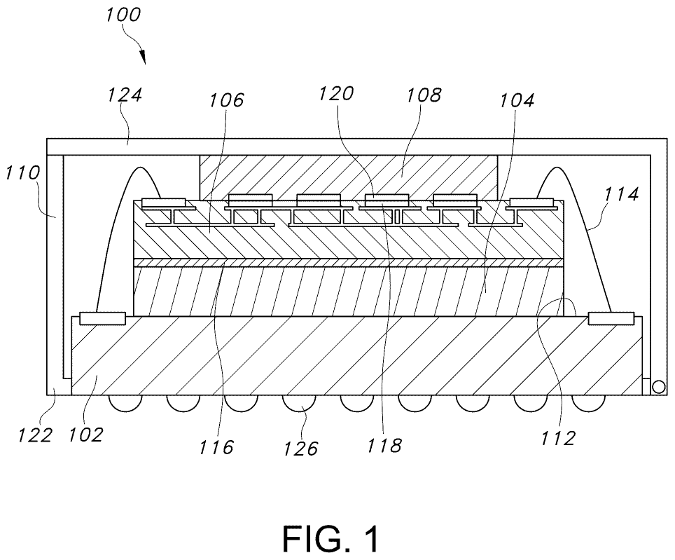

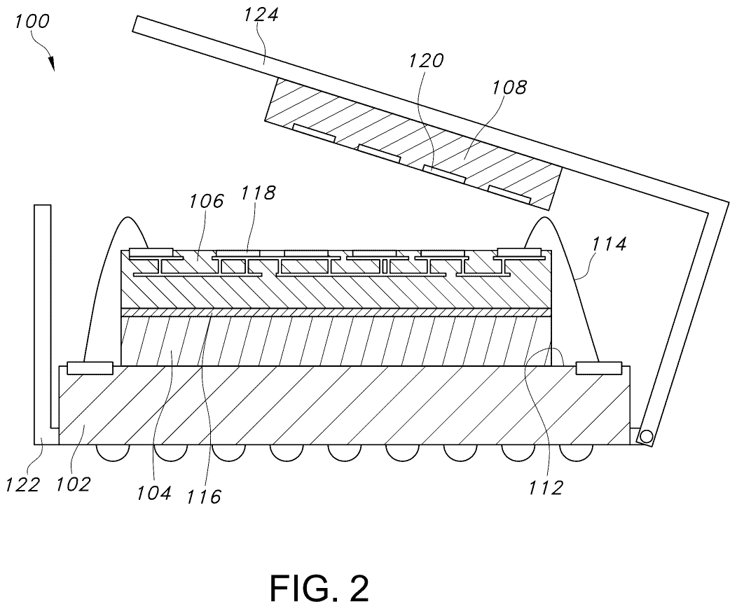

Referring to FIGS. 1-2, there is shown a portion of a multi-chip package (MCP), generally designated 100, in accordance with an exemplary embodiment of the present disclosure. The MCP 100 may include a substrate 102, a first semiconductor module 104, an interposer 106, a second semiconductor module 108 and a housing 110. The MCP 100 may be any type of multi-chip package, such as, but not limited to, a system-in-package (SiP), a system-on-package (SoP), a hybrid circuit (HC), a hybrid integrated circuit (HIC), a multi-chip module (MCM), a universal flash storage (UFS) based MCP (uMCP), or a storage device (e.g., a secure digital (SD) card or a MultiMediaCard (MMC)). In some embodiments, the MCP 100 may include a controller (not shown) configured to control the routing of signals (e.g., power, ground, IO signals) to and from the semiconductor modules 104, 108 and/or interposer 106. In some embodiments, the controller may be an application-specific integrated circuit (ASIC), or any other type of controller. The controller may be electrically connected to the substrate 102.

In some embodiments, each of the semiconductor modules 104, 108 may include one or more semiconductor dies. In some embodiments, each of the semiconductor modules 104, 108 includes at least one semiconductor die. One or more of the semiconductor modules 104, 108 may be memory modules configured to store an amount of electrical charge (e.g., provide a data storage amount). In some embodiments, one or more of the semiconductor modules 104, 108 may be a SiP. In some embodiments, one of the first and second semiconductor modules 104, 108 may be a NAND module and the remaining module may be a DRAM module. For example, in one instance, the first semiconductor module 104 may be a NAND module including one or more NAND dies and the second semiconductor module 108 may be a DRAM module including one or more DRAM dies. In other instances, the first semiconductor module 104 may be a DRAM module and the second semiconductor module 108 may be a NAND module. In some instances, one or both of the semiconductor modules 104, 108 may include one or more semiconductor dies encapsulated by a mold compound. The mold compound may include, for example, an epoxy molding compound (EMC) or other encapsulant material known in the art.

The substrate 102 may be a mechanical base support of MCP 100 and/or an electrical interface that provides access to the semiconductor modules 104, 108 and/or interposer 106 included in the MCP 100. The electrical interface may include a plurality of metal layers within the substrate 102, including at least one layer for routing data using conductive (e.g., copper) traces, a ground layer, and/or a power layer. The substrate 102, in some embodiments, is configured as a printed circuit board to which first semiconductor module 104 and interposer 106 are electrically connected to.

The first semiconductor module 104 may be directly coupled to the substrate 102. In some embodiments, the first semiconductor module 104 may be mounted directly on a top planar surface 112 of the substrate 102 and electrically connected thereto. For example, the first semiconductor module 104 may be electrically connected to the substrate 102 by a through-via connection, flip-chip mounting, surface mount technology (SMT), or any other conventional means known to those skilled in the art. In some embodiments, the first semiconductor module 104 is electrically connected to the substrate 102 via one or more bond wires (not shown). In some embodiments, the position of the first semiconductor module 104 is generally fixed relative to the substrate 102. For example, the first semiconductor module 104 may be fixedly coupled to the substrate 102.

The interposer 106 may be mounted on the first semiconductor module 104 and configured to electrically connect the second semiconductor module 108 to the substrate 102. In some embodiments, the interposer 106 is mounted on the first semiconductor module 104 and electrically connected to the substrate 102. For example, the interposer 106 may be mounted directly on the top surface of the first semiconductor module 104 and electrically connected to the substrate 102 via a plurality of bond wires 114. In some embodiments, the first semiconductor module 104 may be positioned between the interposer 106 and substrate 102. In some embodiments, the interposer 106 may be adhered to the first semiconductor module 104. For example, the interposer 106 may be coupled to the first semiconductor module 104 by a module attach film (DAF) 116 adhered to the top surface of the first semiconductor module 104. In some embodiments, the interposer 106 may substantially cover the top surface of the first semiconductor module 104. For example, the interposer 106 may have a footprint that is generally the same as and aligned with the footprint of the first semiconductor module 104. In other embodiments, the interposer 106 may be smaller in at least one of width and length than the first semiconductor module 104. For example, the footprint of the interposer 106 may be lesser than the footprint of the first semiconductor module 104 in at least one direction to allow for the first semiconductor module 104 to be wire bonded to the substrate 102. In some embodiments, the first semiconductor module 104, interposer 106 and/or bond wires 114 may be encapsulated within a molding compound (not shown) that does not encapsulate the second semiconductor module 108.

The second semiconductor module 108 may be detachable from the MCP 100 to allow for the second semiconductor module 108 to be switched out with a different semiconductor module. In some embodiments, the second semiconductor module 108 is detachably coupled to the interposer 106. The second semiconductor module 108 may be decoupled from the interposer 106 without breaking any components or bonds between the interposer 106 and second semiconductor module 108. In some embodiments, the interposer 106 and second semiconductor module 108 are not permanently coupled to one another. The interposer 106 may be configured to electrically connect the second semiconductor module 108 to the substrate 102. For example, the interposer 106 may include a first plurality of conductive pads 118 configured to directly contact a corresponding second plurality of conductive pads 120 of the second semiconductor module 108 when the second semiconductor module 108 is coupled to the interposer 106. In some embodiments, the first plurality of conductive pads 118 are exposed at a top surface of the interposer 106 such that the first and second plurality of conductive pads 120 may directly contact one another. Conductive pads 118 and 120 may generally have flat contact surfaces according to some embodiments. In some embodiments, the first plurality of conductive pads 118 may be in electrical communication with the bond wires 114. In some embodiments, bond wires 114 in turn may be bonded to and electrically connected to pads on substrate 102. In alternative embodiments, instead of flat conductive pads, second semiconductor module 108 may include a plurality of electrically conductive pins and interposer 106 may include a plurality of sockets for receiving the pins.

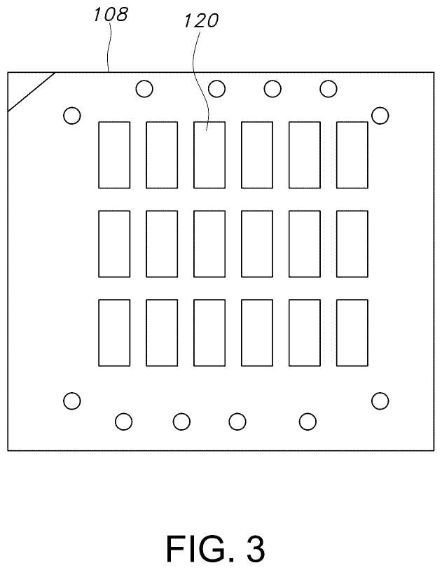

Referring to FIGS. 1 and 3, the second plurality of conductive pads 120 may be exposed at a bottom surface of the second semiconductor module 108 and configured to be electrically connected to the first plurality of conductive pads 118. For example, the arrangement of the second plurality of conductive pads 120 may be substantially the same as the arrangement of the first plurality of conductive pads 118 on the interposer 106. As such, the second semiconductor module 108 may be mounted directly on top of the interposer 106 such that corresponding pads of the first and second plurality of conductive pads 118, 120 are substantially aligned and at least partially abut one another when second semiconductor module 108 is coupled onto interposer 106. In some embodiments, the first and second plurality of conductive pads 118, 120 may not be fixedly coupled to one another to allow for the second semiconductor module 108 to be selectively detachable from the interposer 106. In some such embodiments, there are no permanent bonds (e.g., solder bonds) between conductive pads 118 and conductive pads 120. Moreover, in some embodiments, there is no adhesive layer between interposer 106 and second semiconductor module 108.

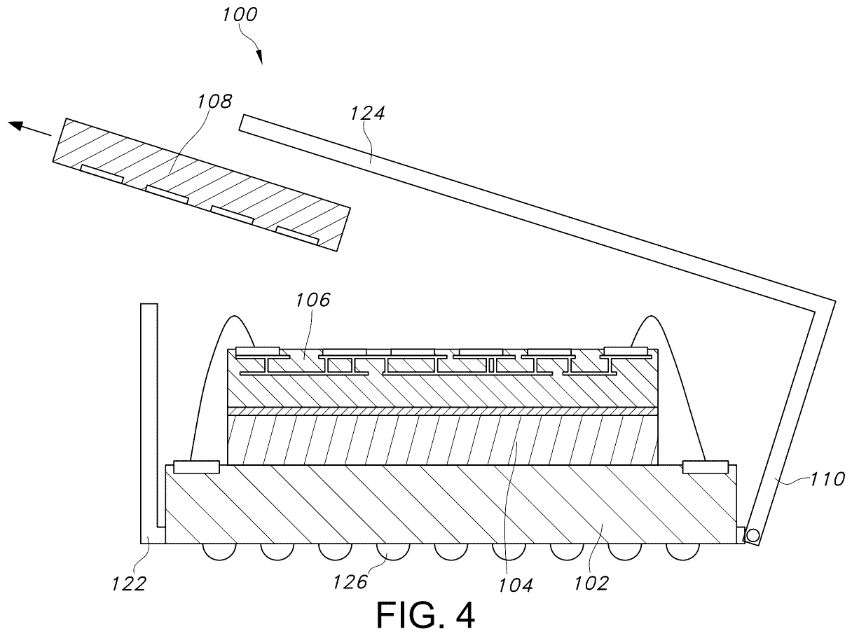

Referring back to FIGS. 1-2, in some embodiments, the housing 110 is configured to releasably retain the second semiconductor module 108 against the interposer 106. The housing 110 may at least partially enclose the first and second semiconductor modules 104, 108 and the interposer 106. In some embodiments, the housing 110 is configured to transition between a closed configuration (shown in FIG. 1) and an open configuration (shown in FIG. 2). In the closed configuration, the housing 110 may be configured to fix the position of the second semiconductor module 108 relative to the interposer 106 such that the second semiconductor module 108 is electrically connected to the substrate 102 via the interposer 106. For example, when in the closed configuration, the housing 110 may be configured to align the first and second plurality of conductive pads 118, 120 such that they directly contact one another. In some embodiments, housing 110 in the closed configuration is configured to apply a clamping force that is sufficient to hold second semiconductor module 108 against interposer 106 in order to maintain the position of second semiconductor module 108 relative to interposer 106 and to maintain physical contact between conductive pads 120 and conductive pads 118. In some embodiments, housing 110 in the closed configuration biases second semiconductor module 108 toward interposer 106. In the open configuration, the housing 110 may be configured to permit the second semiconductor module 108 to be detached from the interposer 106. For example, when the housing 110 is in the open configuration (shown in FIGS. 2 and 4) the second semiconductor module 108 may not directly contact the interposer 106 to allow for the second semiconductor module 108 to be decoupled from the MCP 100 (as shown in FIG. 4).

When in the open configuration the second semiconductor module 108 may be replaced (e.g., by a user) with another semiconductor module, chip or module. This may be particularly beneficial in instances where the second semiconductor module 108 is non-operational (e.g., is damaged, breaks) and/or in other instances where it is desirable to replace the second semiconductor module 108. For example, in some embodiments, the second semiconductor module may be a NAND module, or NAND chip/module, having a first storage capacity (e.g., 528 megabytes) and it may be desirable to replace the NAND module with another having a higher storage capacity (e.g., 1 terabyte). In this manner, the MCP 100 of the present disclosure may be upgradable and/or reparable as compared to conventional MCPs in which none of the modules or chips included therein are detachable. The replacement module may therefore be the same as or different than the second semiconductor module 108 depending on the need of the user. In some embodiments, the replacement module may have a plurality of conductive pads in the same configuration and arrangement as conductive pads 120 in order to contact conductive pads 118 of the interposer 106.

In some embodiments, the housing 110 includes a base plate 122 and a cover 124 movably coupled to the base plate 122. The base plate 122 may be fixed to substrate 102 in some embodiments. The cover 124 may be movable between a first position, shown in FIG. 1, in the closed configuration to a second position, shown in, for example, FIG. 2, in the open position. For example, and as illustrated in FIGS. 1-2 and 4, the cover 124 may be rotatably coupled to the base plate 122 such that the cover 124 may be rotated relative to the base plate 122 between the first and second position. In some embodiments, cover 124 may be coupled to base plate 122 via one or more hinges that allow rotation of cover 124 with respect to base plate 122 from the first position (e.g., a closed position) to the second position (e.g., an open position), and vice versa. In other embodiments, the cover 124 is detachable from the base plate 122. For example, the cover 124 may be snap fit to the base plate 122 or detachably coupled thereto by one or more fasteners. In some embodiments, the cover 124 may be configured to act as a pressure closure of the housing 110. In some embodiments, housing 110 includes a lock for preventing housing 110 from transitioning from the closed configuration to the open configuration until housing 110 is unlocked by a user. For example, when housing 110 is locked, cover 124 may be prevented from rotating with respect to base plate 122.

In some embodiments, the housing 110 is configured to prevent or at least reduce the risk of the first semiconductor module 108 moving relative to the interposer 106 when the housing 110 is in the closed configuration. In the first position, the cover 124 may abut against the second semiconductor module 108 and bias the second semiconductor module 108 towards the interposer 106. For example, when in the first position the cover 124 may abut against a top surface of the second semiconductor module 108 and apply a downward force thereto to bias the second semiconductor module 108 towards the interposer 106. In this manner, the cover 124 may be configured to fix the position of the second semiconductor module 108 relative to the interposer 106 when the housing 110 is in the closed configuration.

In some embodiments, the second semiconductor module 108 is configured to separate from interposer 106 and move with the cover 124 when cover 124 is transitioned from the first (closed) position towards the second (open) position. In some embodiments, the second semiconductor module 108 is detachably coupled to the cover 124. The second semiconductor module 108, when coupled to the cover 124, may be movable relative to the base plate 122 with the cover 124. For example, the position of the second semiconductor module 108, when coupled to the cover 124, may be fixed relative to the cover 124 as the cover 124 moves between the first and second position. In some embodiments, the cover 124 includes a coupling mechanism or structure (not shown) configured to detachably couple the second semiconductor module 108 thereto. The coupling device or structure may include, for example, a slot or receiving aperture sized to receive at least a portion of the second semiconductor module 108, or a mounting bracket. In some embodiments, the cover 124 is configured to position the second semiconductor module 108 relative to the interposer 106 such that when the housing 110 is in the closed configuration the second semiconductor module 108 and interposer 106 are in electrical communication with one another. For example, the coupling device or structure of the cover 124 may be fixedly coupled to the cover 124 at a predetermined position such that when the second semiconductor module 108 is coupled thereto and the housing 110 is in the closed configuration the first and second plurality of conductive pads 118, 120 are aligned with and abut one another. In some embodiments, the cover 124 is a clamshell cover.

In some embodiments, the substrate 102, first semiconductor module 104 and/or interposer 106 are fixed relative to the base plate 122 of the housing 110. The substrate 102 may be coupled to the base plate 122 and fixed in position relative to the base plate 122. The first semiconductor module 104 may be fixed in position relative to the substrate 102 and the interposer 106 may be fixed in position relative to the first semiconductor module 104. For example, the first semiconductor module 104 may be fixedly coupled to the substrate 102 and the interposer 106 may be fixedly coupled to the first semiconductor module 104. In this manner, the position of the substrate 102, first semiconductor module 104, and/or interposer 106 may be fixed relative to the base plate 122. In some embodiments, the substrate 102 includes a ball grid array 126 configured to enable the MCP 100 to be electrically and/or mechanically connected to one or more additional devices or components. In some embodiments, at least some of the balls in the ball grid array 126 are configured to transmit electrical signals to and from first semiconductor module 104 and/or second semiconductor module 108 via substrate 102. The ball grid array 126 may extend at least partially outside of the housing 110 to permit the ball grid array 126 to be mounted on, or connected to, a corresponding set of conductive pads included in, for example, a second PCB. In some embodiments, the ball grid array 126 is electrically connected to the substrate 102 and extends downwardly from a bottom surface of the substrate 102. In some embodiments, the ball grid array 126 may extend at least partially below the bottom surface of the base plate 122.

In some embodiments, the housing 110 is configured to act as a heat sink to improve heat dissipation capabilities of the MCP 100 when compared to conventional MCPs. For example, at least a portion of the cover 124 and/or base plate 122 may be comprised of a thermally conductive material. In some embodiments, the cover 124 and/or base plate 122 are comprised of a material having a thermal conductivity of at least 150 W/m*K. In some embodiments, the cover 124 and/or base plate 122 are comprised of a material having a thermal conductivity of at least 200 W/m*K. In some embodiments, the cover 124 and/or base plate 122 are comprised of a material having a thermal conductivity of between about 80 W/m*K to about 400 W/m*K. In some embodiments, the cover 124 and/or base plate 122 are comprised of a metal and/or metal alloy (e.g., aluminum, aluminum alloy, copper or copper alloy). In some embodiments, the cover 124 and base plate 122 are comprised of the same material. In other embodiments, the cover 124 and base plate 122 are comprised of different materials. In some embodiments, the housing 110, when in the closed configuration, may have a length of about 11.50 mm, a width of about 13.00 mm and a height of about 1.2 mm.

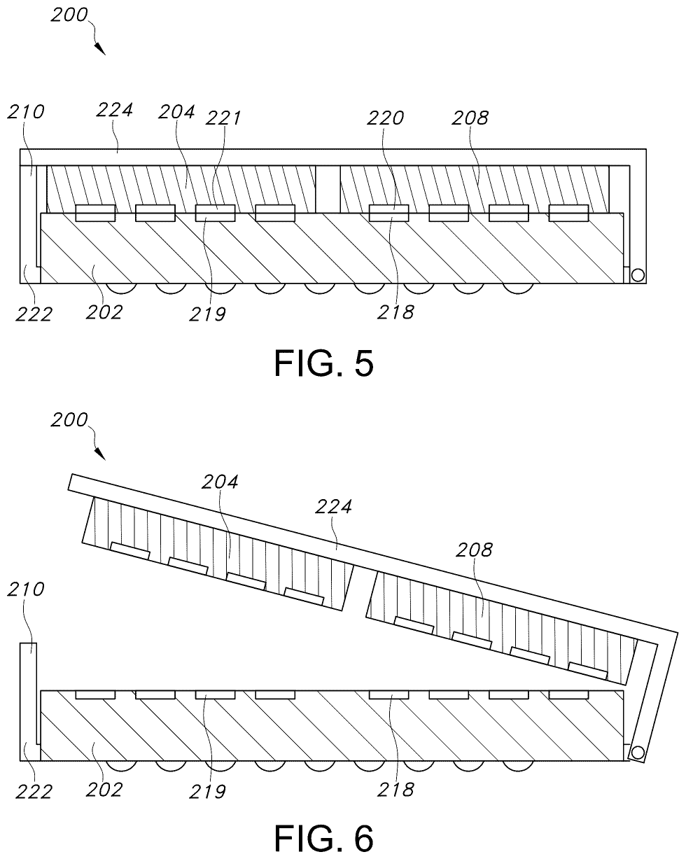

Referring to FIGS. 5-6, there is shown a portion of a MCP, generally designated 200, in accordance with another exemplary embodiment of the present disclosure. The MCP 200 may be generally the same as MCP 100 in terms of function as discussed above with reference to FIGS. 1-4 except that both the first semiconductor module 204 and second semiconductor module 208 may be detachable from the MCP 200. Similar to housing 110, the housing 210 may be configured to transition between a closed configuration, illustrated in FIG. 5, and an open configuration, illustrated in FIG. 6. In some embodiments, unlike the stacked configuration shown in FIGS. 1-4, the first semiconductor module 204 and second semiconductor module 208 may each be configured to couple directly to the substrate 202 when the housing 210 is in the closed configuration. In the closed configuration, both the first and second semiconductor modules 204, 208 may be fixed in position relative to the substrate 202 and electrically connected thereto. In some embodiments, the first and second semiconductor modules 204, 208 are in fixed position relative to each other when housing 210 is in the closed configuration. The substrate 202 may be generally the same as substrate 102 except that the substrate 202 may include a first set of conductive pads 219 and a second set of conductive pads 218 exposed at a top surface of the substrate 202. Each of the semiconductor modules 204, 208 may be generally the same as semiconductor modules 104, 108 except that the first semiconductor module 204 may also include a corresponding set of bond pads configured to electrically connect the first semiconductor module 204 to the substrate 202. The first and second semiconductor modules 204, 208 may include a corresponding third and fourth set of bond pads 221, 220 exposed at a bottom surface of each. In some embodiments, the MCP 200 may not include an interposer coupled to the first and/or second semiconductor modules 204, 208. In other embodiments, the MCP 200 may include an interposer (not shown) positioned between the substrate 202 and semiconductor modules 204, 208 and configured to electrically connect the semiconductor modules 204, 208 to the substrate 202.

When the housing 210 is in the closed configuration, the first and second semiconductor modules 204, 208 may be biased towards the substrate 202. In some embodiments, housing 210 in the closed configuration is configured to apply a clamping force that is sufficient to hold the first and the second semiconductor modules 204, 208 against substrate 202 in order to maintain the positions of the first and the second semiconductor modules 204, 208 relative to substrate 202 and to maintain physical contact between conductive pads 220, 221 and conductive pads 218, 219, respectively. In some embodiments, the housing 210 may include a cover 224 generally the same as cover 124 and a base plate 222 generally the same as base plate 122. The cover 224 may be movable relative to the base plate 222 between a first position, when in the closed configuration, and a second position, when in the open configuration. In some embodiments, when in the first position, the cover 224 may abut against the first and second semiconductor modules 204, 208 and bias each toward the substrate 202. In some embodiments, the cover 224 is rotatably coupled to the base plate 222 such that the cover 224 may rotate relative to the base plate 222 between the first and second positions. In other embodiments, the cover 224 is detachable from the base plate 222 in one or more manners similar to those described above with reference to the cover 124 and base plate 122.

When the housing 210 is in the open configuration, the first and second semiconductor modules 204, 208 may be detachable from the MCP 200. In some embodiments, when in the second position, the cover 224 may be configured to permit detachment of the first and second semiconductor modules 204, 208 from the substrate 202. For example, when in the second position, the cover 224 may provide an opening in the housing 210 within which a user may manually decouple the semiconductor modules 204, 208 from the substrate 202. In some embodiments, the first and second semiconductor modules 204, 208 may be coupled to the cover 224 such that each is movable relative to the base plate 222 with the cover 224. For example, each of the first and second semiconductor modules 204, 208 may be coupled to the cover 224, in generally the same manner as described above with reference to MCP 100, such that when the cover 224 is moved (e.g., rotated) relative to the base plate 222, the first and second semiconductor modules 204, 208 remain coupled to the cover 224. In some embodiments, the first and second semiconductor modules 204, 208 are detachably coupled to the cover 224 such that a user may move the cover 224 to the second position and decouple one or more of the first and second semiconductor modules 204, 208 therefrom.

When in the open configuration the first and second semiconductor modules 204, 208 may be selectively replaced (e.g., by a user) with another semiconductor module, chip or module. This may be particularly beneficial in instances where one or both of the first and second semiconductor modules 204, 208 are non-operational (e.g., is damaged, breaks) and/or in other instances where it is desirable to replace one with another module, chip or module. For example, in some embodiments, one or more of the first and second semiconductor modules 204, 208 may be a

NAND module, or NAND chip/module, having a first storage capacity (e.g., 528 megabytes) and it may be desirable to replace the NAND module with another having a higher storage capacity (e.g., 1 terabyte). In this manner, the MCP 200 of the present disclosure may be upgradable and/or reparable as compared to conventional MCPs in which none of the modules or chips included therein are detachable.

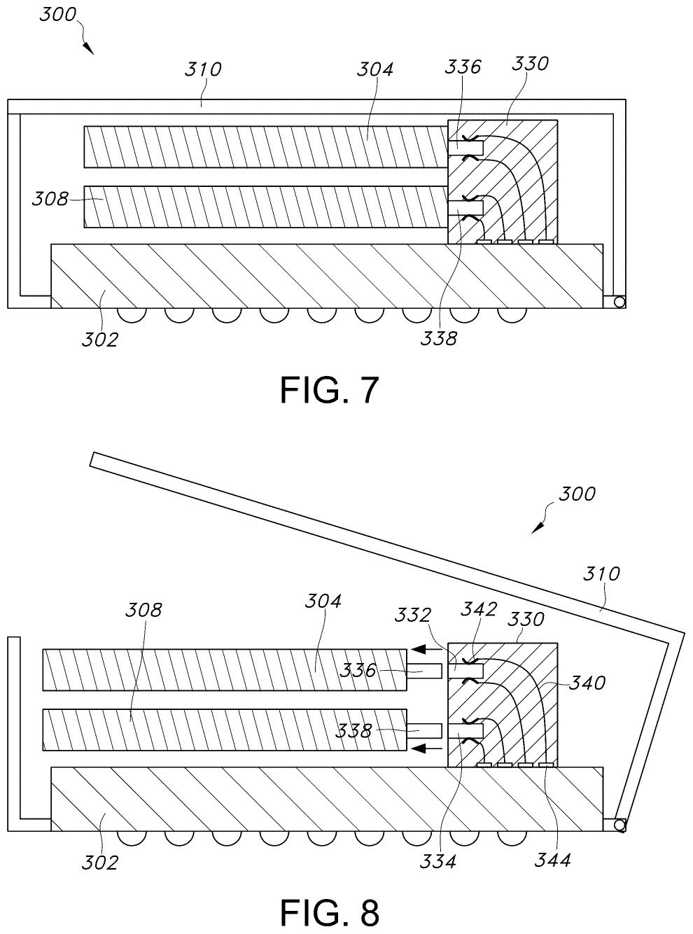

Referring to FIGS. 7-8, there is shown another MCP, generally designated 300, in accordance with another exemplary embodiment of the present disclosure. The MCP 300 may be generally the same as MCP 200 except that the MCP 300 may include an electrical interface hub 330 configured to detachably connect the first and second semiconductor modules 304, 308 to the substrate 302. The electrical interface hub 330 may include a first receiving slot 332 and a second receiving slot 334 each in electrical communication with the substrate 302. In some embodiments, the receiving slots 332 and 334 may be configured to electrically and/or mechanically couple the first and second semiconductor modules 304, 308 to the substrate 302. For example, each of the semiconductor modules 304, 308 may be generally the same as semiconductor modules 104, 108, 204, 208 as described above, except that they may include a corresponding edge connector 336, 338 instead of conductive pads exposed at a bottom surface thereof. The edge connectors 336, 338 may be configured to be received within a corresponding slot 332, 334 to electrically and mechanically connect the semiconductor modules 304, 308 to the electrical interface hub 330. In this manner, the first and second semiconductor modules 304, 308 may be individually detachable from the electrical interface hub 330 and MCP 300.

In some embodiments, there may be a plurality of bond wires 340 electrically connecting the first and second receiving slots 332, 334 to the substrate 302. There may be a plurality of socket connectors 342 electrically connected to each receiving slot 332, 334. Each of the bond wires 340 may be electrically connected to a corresponding socket connector 342. In some embodiments, there may be a plurality of conductive pads 344 (e.g., SMT pads) electrically connected to the substrate 302. Each of the bond wires 340 may be electrically connected to a corresponding conductive pad 344. In this manner, each of the bond wires 340 may electrically connect the receiving slots 332, 334 to the substrate 302.

In some embodiments, MCP 300 further includes a housing 310 that encloses, at least partially, the first and second semiconductor modules 304, 308 and the electrical interface hub 330. For example, the housing 310 may be generally the same as housings 110 and/or 210 as described above. The housing 310 may be configured to transition between a closed configuration, shown in FIG. 7, and an open configuration, shown in FIG. 8. When in the closed configuration, the housing 310 may not directly abut either of the semiconductor modules 304, 308 or apply a force thereon. When in the open configuration, the housing 310 may permit access to the interior of the housing 310 to enable a user to selectively detach one or more of the semiconductor modules 304, 308 from the electrical interface hub 330 as illustrated in FIG. 8. In this manner, the semiconductor modules 304, 308 may be selectively detachable from the MCP 300 such that a user may replace any damaged modules with replacement modules, chips, or modules and/or replace an existing NAND module with another having, for example, a higher storage capacity as described above with reference to MCP 100.

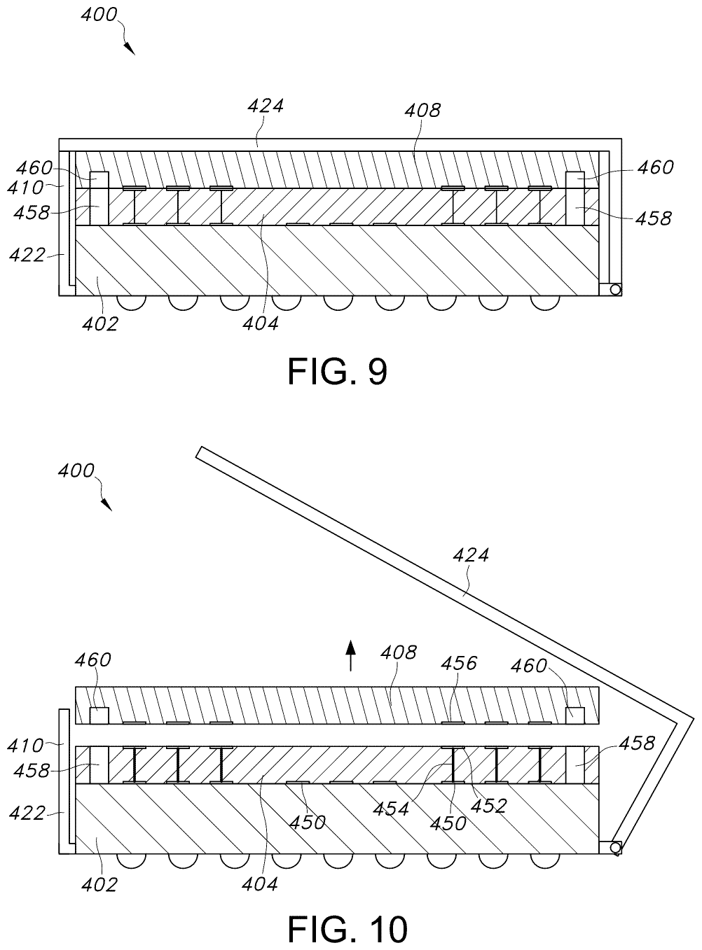

Referring to FIGS. 9-10, there is shown another MCP, generally designated 400, in

accordance with another exemplary embodiment of the present disclosure. The MCP 400 may be generally the same as MCP 100 discussed above with regards to FIGS. 1-4 except that the MCP 400 may include a magnetic coupling means for detachably coupling the second semiconductor module 408 to the first semiconductor module 404. The MCP 400 may also be different from the MCP 100 in that the MCP 400 may not include the interposer 106. For example, the second semiconductor module 408 may, when electrically connected to the substrate 402, be mounted directly on the first semiconductor module 404. In some embodiments, the first semiconductor module 404 is electrically connected to and mounted directly on the substrate 402. For example, there may be a first plurality of bond pads 450 (e.g., SMT pads) electrically connecting and/or mechanically coupling the first semiconductor module 404 to the substrate 402. In this manner, the first semiconductor module 404 may be soldered to the substrate 402. In some embodiments, one or more of the first plurality of bond pads 450 may mechanically couple the first semiconductor module 404 to the substrate 402 and may be configured to electrically connect the second semiconductor module 408 thereto. In some instances, the bond pads 450 configured to electrically connect the second semiconductor module 408 to the substrate 402 may not electrically connect the first semiconductor module 404 to the substrate 402.

The first semiconductor module 404 may be generally the same as the first semiconductor module 104 except that it may include a second plurality of bond pads 452 configured to electrically connect to the second semiconductor module 408. The second plurality of bond pads 452 may be exposed at a top surface of the first semiconductor module 404 and configured to electrically connect the second semiconductor module 408 to the substrate 402. The second plurality of bond pads 452 may be electrically connected to one or more of the first plurality of bond pads 450 by through-vias 454 that extend through the first semiconductor module 404. In some embodiments, the number of second bond pads 452 is less than the number of first bond pads 450 included in the MCP 400. In some embodiments, the through-vias 454 may be electrically isolated from semiconductor dies included in the first semiconductor module 404.

The second semiconductor module 408 may include a third plurality of bond pads 456 exposed at a bottom surface thereon. The third plurality of bond pads 456 may be configured to be electrically connected to and/or mounted directly on the second plurality of bond pads 452. For example, the second and third pluralities of bond pads 452, 456 may be aligned with one another and directly contact one another when the second semiconductor module 408 is mounted on the first semiconductor module 404 (as shown in FIG. 9). In this manner, the second and third pluralities of bond pads 452, 456 may electrically connect the second semiconductor module 408 to the substrate 402.

In some embodiments, each of the semiconductor modules 404, 408 may include a corresponding plurality of magnets configured to detachably couple the first and second semiconductor modules 404, 408 to one another. The first semiconductor module 404 may include a first plurality of magnets 458 and the second semiconductor module 408 may include a second plurality of magnets 460. In some embodiments, the second plurality of magnets 460 are configured to be aligned with the first plurality of magnets 458 when the semiconductor module 408 is coupled to semiconductor module 404. In some embodiments, the second plurality of magnets 460 are configured to contact the first plurality of magnets 458 when the semiconductor module 408 is coupled to semiconductor module 404. In some embodiments, the magnets 458 and 460 are exposed on the respective top and bottom surfaces of the first and second semiconductor modules 404, 408. In some embodiments, the attractive magnetic force between the first plurality of magnets 458 and the second plurality of magnets 460 aids in securing the position of semiconductor module 408 with respect to semiconductor module 404. In some embodiments, semiconductor module 408 remains detachable from semiconductor module 404 by applying a force sufficient to overcome the magnetic force when housing 410 is in the open configuration.

In some embodiments, each of the first and second semiconductor modules 404, 408 includes at least two corresponding magnets 458, 460. In some embodiments, by providing the corresponding magnets 458, 460 in the first and second semiconductor modules 404, 408, the second semiconductor module 408 may be easily decoupled from the first semiconductor module 404. For example, and as illustrated in FIG. 10, the housing 410 may transition from a closed configuration (e.g., as shown in FIG. 9) to an open configuration (e.g., as shown in FIG. 10) in which the second semiconductor module 408 may be removed from the MCP 400. In some embodiments, the housing 410 may be generally the same as housing 110. The cover 424 may, when the housing 410 is in the closed configuration, abut the second semiconductor module 408 and bias the second semiconductor module 408 towards the first semiconductor module 404. In some embodiments, the first and second magnets 458, 460 are permanent magnets.

It will be appreciated by those skilled in the art that changes could be made to the exemplary embodiments shown and described above without departing from the broad inventive concepts thereof. It is understood, therefore, that this invention is not limited to the exemplary embodiments shown and described, but it is intended to cover modifications within the spirit and scope of the present invention as defined by the claims. For example, specific features of the exemplary embodiments may or may not be part of the claimed invention and various features of the disclosed embodiments may be combined. The words “right”, “left”, “lower” and “upper” designate directions in the drawings to which reference is made. Unless specifically set forth herein, the terms “a”, “an” and “the” are not limited to one element but instead should be read as meaning “at least one”. As used herein, the term “about” may refer to +/−10% of the value referenced. For example, “about 9” is understood to encompass 8.1 and 9.9.

It is to be understood that at least some of the figures and descriptions of the invention have been simplified to focus on elements that are relevant for a clear understanding of the invention, while eliminating, for purposes of clarity, other elements that those of ordinary skill in the art will appreciate may also comprise a portion of the invention. However, because such elements are well known in the art, and because they do not necessarily facilitate a better understanding of the invention, a description of such elements is not provided herein.

Further, to the extent that the methods of the present invention do not rely on the particular order of steps set forth herein, the particular order of the steps should not be construed as limitation on the claims. Any claims directed to the methods of the present invention should not be limited to the performance of their steps in the order written, and one skilled in the art can readily appreciate that the steps may be varied and still remain within the spirit and scope of the present invention.

What is claimed is:

1. A multi-chip package comprising:
a substrate;
a first semiconductor module mounted directly on a top planar surface of the substrate and electrically connected thereto;
an interposer mounted on the first semiconductor module and electrically connected to the substrate;
a second semiconductor module detachably coupled to the interposer; and
a housing at least partially enclosing the first and second semiconductor modules and interposer, the housing configured to transition between a closed configuration and an open configuration,
wherein in the closed configuration, the second semiconductor module is fixed in position relative to the interposer and electrically connected to the substrate via the interposer, and in the open configuration the second semiconductor module is detachable from the interposer.

2. The multi-chip package of claim 1, wherein the first semiconductor module is a NAND module and the second semiconductor module is a dynamic random access memory (DRAM) module.

3. The multi-chip package of claim 1, wherein the first semiconductor module is a DRAM module and the second semiconductor module is a NAND module.

4. The multi-chip package of claim 1, wherein the housing includes a base plate coupled to the substrate and a cover movably coupled to the base plate, the cover being movable from a first position in the closed configuration to a second position in the open configuration.

5. The multi-chip package of claim 4, wherein in the first position the cover abuts against the second semiconductor module and biases the second semiconductor module towards the interposer, and
wherein in the second position the cover is configured to permit detachment of the second semiconductor module from the interposer.

6. The multi-chip package of claim 4, wherein the second semiconductor module is coupled to the cover such that the second semiconductor module is movable relative to the base plate with the cover.

7. The multi-chip package of claim 4, wherein the cover comprises a heat sink composed of a material having a thermal conductivity of at least about 150 W/m*K.

8. The multi-chip package of claim 1, wherein in the closed configuration the second semiconductor module is stacked on the first semiconductor module, and the interposer is disposed between the first semiconductor module and the second semiconductor module.

9. The multi-chip package of claim 4, wherein the interposer includes a first plurality of conductive pads, and
wherein the second semiconductor module includes a second plurality of conductive pads configured to directly contact the first plurality of conductive pads when the housing is in the closed configuration.

10. The multi-chip package of claim 9, wherein in the closed configuration the cover is configured to apply an amount of pressure on the second semiconductor module and first semiconductor module sufficient to prevent the first and second plurality of conductive pads from moving out of direct contact with one another.

11. The multi-chip package of claim 1, wherein there are a plurality of bond wires electrically connecting the interposer to the substrate.

12. A multi-chip package comprising:
a substrate;
a first semiconductor module detachably coupled to the substrate;
a second semiconductor module detachably coupled to the substrate and spaced from the first semiconductor module; and
a housing at least partially enclosing the first and second semiconductor modules, the housing configured to transition between a closed configuration and an open configuration, the housing including a base plate and a cover movably coupled to the base plate, the cover being movable from a first position in the closed configuration to a second position in the open configuration,
wherein in the closed configuration, the first and second semiconductor modules are fixed in position relative to the substrate and electrically connected to the substrate, and in the open configuration the first and second semiconductor modules are detachable from the substrate,
wherein in the first position the cover abuts against the first and second semiconductor modules and biases each towards the substrate, and in the second position the cover is configured to permit detachment of the first and second semiconductor modules from the substrate.

13. The multi-chip package of claim 12, wherein the first semiconductor module is a NAND module and the second semiconductor module is a dynamic random access memory (DRAM) module.

14. The multi-chip package of claim 12, wherein the cover comprises a heat sink composed of a material having a thermal conductivity of at least about 150 W/m*K.

15. The multi-chip package of claim 12, wherein the substrate includes a first and second set of conductive pads, the first semiconductor module includes a third set of conductive pads, and the second semiconductor module includes a fourth set of conductive pads, the third and fourth sets of conductive pads configured to directly contact the corresponding first and second set of conductive pads when the housing is in the closed configuration.

16. The multi-chip package of claim 12, wherein in the closed configuration the cover is configured to apply an amount of pressure on the second semiconductor module and first semiconductor module sufficient to prevent the first, second, third and fourth sets of conductive pads from moving out of direct contact with one another.

17. The multi-chip package of claim 12, wherein the first and second semiconductor modules are coupled to the cover such that the first and second semiconductor modules are moveable relative to the base plate with the cover, and wherein the substrate is coupled to the base plate.

18. A multi-chip package comprising:
a substrate;
a first semiconductor module mounted directly on a top planar surface of the substrate and electrically connected thereto, the first semiconductor module including a first plurality of magnets;
a second semiconductor module mounted to the first semiconductor module and including a second plurality of magnets detachably coupling the second semiconductor module to the first semiconductor module; and
a housing at least partially enclosing the first and second semiconductor modules, the housing configured to transition between a closed configuration and an open configuration,
wherein in the closed configuration, the second semiconductor module is fixed in position relative to the first semiconductor module and electrically connected to the substrate, and in the open configuration the second semiconductor module is detachable from the first semiconductor module.

19. The multi-chip package of claim 18, wherein the first semiconductor module is a NAND module and the second semiconductor module is a dynamic random access memory (DRAM) module.

20. The multi-chip package of claim 18, wherein the first semiconductor module is a DRAM module and the second semiconductor module is a NAND module.
